(19) United States
(12) Patent Application Publication
(10) Pub. No.: US 2024/0014182 A1
(43) Pub. Date: Jan. 11, 2024

(54) BACKLIGHT MODULE AND DISPLAY DEVICE

(71) Applicant: Xi Cheng, (US)

(72) Inventor: Xi Cheng, (US)

(21) Appl. No.: 17/419,854

(22) PCT Filed: May 12, 2021
(86) PCT No.: PCT/CN2021/093224

§ 371 Date: Oct. 27, 2022

(51) Int. Cl. H01L 25/075; H01L 33/20

(52) U.S. Cl. CPC H01L 25/0753; H01L 33/20

(57) ABSTRACT

The present application discloses a backlight module and a display device. The backlight module includes a substrate, a plurality of LED chips, and a sealant layer. The plurality of LED chips are arranged on the substrate at intervals, and the sealant layer is arranged on the substrate and covers the plurality of LED chips; the sealant layer is provided with a plurality of recesses on a side away from the LED chips, and the plurality of recesses is arranged above the plurality of LED chips in a one-to-one correspondence to the plurality of LED chips, so that light directly above the LED chips is opened to surroundings, and side light emission of the LED chips is increased, thereby increasing brightness of an area between adjacent ones of the LED chips, thus reducing a probability of dark shadows occurring.

### BACKGROUND OF INVENTION

### Field of Invention

The present application relates to the field of display technology, and in particular to a backlight module and a display device.

### Description of Prior Art

Compared with traditional backlights, mini light-emitting diode (mini LED) backlights have characteristics of ultra-thinness, high-brightness, multiple partitions, etc. Therefore, industry generally uses mini LEDs as backlights for liquid crystal displays.

A size and pitch, as well as required optical distance (OD) of the mini-LED are key determining parameters for a thickness and cost of a whole device. When a product adopts a thin-type design, requirement for the OD of the backlight gets higher and higher, that is, a shorter OD is required to meet the demand. However, limited by a light-emitting angle and light-emitting uniformity of an LED chip, the OD cannot be further reduced. When the OD is kept to a minimum, since light emitted by the LED chip is concentrated directly above the LED chip, the light is uneven, which results in relatively low brightness in an area between two adjacent LED chips, which tends to form dark shadows and reduce display taste.

In summary, there is an urgent need to provide a backlight module and a display device to solve the above technical problems.

### SUMMARY OF INVENTION

The present application provides a backlight module and a display device to solve the technical problem of the existing backlight module and display device that the center brightness of light emitted by an LED chip is relatively high, and surrounding brightness of the light is relatively low, which causes a dark shadow to be easily formed between adjacent ones of the LED chips.

In order to solve the above problems, the technical solutions provided by the present application are as follows:

The present application provides a backlight module, including:
a substrate;
a plurality of LED chips arranged on the substrate at intervals; and
a sealant layer disposed on the substrate and covering the plurality of LED chips, wherein a material of the sealant layer includes silicone;
wherein the sealant layer is provided with a plurality of recesses on a side away from the LED chips, and the plurality of recesses are arranged above the plurality of LED chips in a one-to-one correspondence to the plurality of LED chips.

According to the backlight module provided by the present application, a shape of a cross-section of each of the recesses in a direction perpendicular to a surface of the substrate is any one of a “V” shape, a “C” shape, or a “-” shape.

According to the backlight module provided by the present application, the LED chips and the recesses are symmetrically arranged with respect to a same symmetry axis.

According to the backlight module provided by the present application, a width of each of the recesses in a direction parallel to a surface of the substrate is greater than a width of each of the LED chips in a direction parallel to the surface of the substrate.

According to the backlight module provided by the present application, each of the recesses includes a first sub-recess and a second sub-recess that are connected to each other, the first sub-recess is formed by recessing inwardly from a top of the sealant layer, and the second sub-recess is further recessed inwardly from a bottom of the first sub-recess, and the first sub-recess surrounds the second sub-recess.

According to the backlight module provided by the present application, a shape of a cross-section of the second sub-recess in a direction perpendicular to a surface of the substrate is any one of a “V” shape, a “C” shape, or a “-” shape, a shape of a cross-section of the first sub-recess in the direction perpendicular to the surface of the substrate is an upper structure of any one of a “V” shape, a “C” shape, or a “-” shape, and the cross sections of the first sub-recess and the second sub-recess have different shapes in the direction perpendicular to the surface of the substrate,

According to the backlight module provided by the present application, the recesses and the sealant layer are formed by a same manufacturing process; and the recesses and the sealant layer are formed by a process of glue dispensing, screen printing, or mold injection.

According to the backlight module provided by the present application, the sealant layer includes a plurality of sub-sealant layers distributed at intervals in a one-to-one correspondence to the plurality of LED chips, and each of the sub-sealant layers covers a corresponding one of the LED chips.

According to the backlight module provided by the present application, a shape of a cross-section of the sub-sealant layers is arc or rectangular.

According to the backlight module provided by the present application, the backlight module further includes an optical film set, and the optical film set is disposed on a side of the sealant layer away from the LED chips.

The present application provides a backlight module, including:
a substrate;
a plurality of LED chips arranged on the substrate at intervals; and
a sealant layer disposed on the substrate and covering the plurality of LED chips;
wherein the sealant layer is provided with a plurality of recesses on a side away from the LED chips, and the plurality of recesses are arranged above the plurality of LED chips in a one-to-one correspondence to the plurality of LED chips.

According to the backlight module provided by the present application, a shape of a cross-section of each of the recesses in a direction perpendicular to a surface of the substrate is any one of a “V” shape, a “C” shape, or a “-” shape.

According to the backlight module provided by the present application, the LED chips and the recesses are symmetrically arranged with respect to a same symmetry axis.

According to the backlight module provided by the present application, a width of each of the recesses in a direction parallel to a surface of the substrate is greater than a width of each of the LED chips in a direction parallel to the surface of the substrate.

According to the backlight module provided by the present application, each of the recesses includes a first sub-recess and a second sub-recess that are connected to each other, the first sub-recess is formed by recessing inwardly from a top of the sealant layer, and the second sub-recess is further recessed inwardly from a bottom of the first sub-recess, and the first sub-recess surrounds the second sub-recess.

According to the backlight module provided by the present application, a shape of a cross-section of the second sub-recess in a direction perpendicular to a surface of the substrate is any one of a “V” shape, a “C” shape, or a “-” shape, a shape of a cross-section of the first sub-recess in the direction perpendicular to the surface of the substrate is an upper structure of any one of a “V” shape, a “C” shape, or a “-” shape, and the cross sections of the first sub-recess and the second sub-recess have different shapes in the direction perpendicular to the surface of the substrate.

According to the backlight module provided by the present application, the recesses and the sealant layer are formed by a same manufacturing process; and the recesses and the sealant layer are formed by a process of glue dispensing, screen printing, or mold injection.

According to the backlight module provided by the present application, the sealant layer includes a plurality of sub-sealant layers distributed at intervals in a one-to-one correspondence to the plurality of LED chips, and each of the sub-sealant layers covers a corresponding one of the LED chips.

According to the backlight module provided by the present application, a shape of a cross-section of the sub-sealant layers is arc or rectangular.

The present application also provides a display device including the above-mentioned backlight module; and

a display panel disposed on a side of the light-exiting surface of the backlight module.

Beneficial effects of the present application are that: the backlight module and display device provided by the present application include a substrate, a plurality of LED chips, and a sealant layer. The plurality of LED chips are arranged on the substrate at intervals, and the sealant layer is arranged on the substrate and covers the plurality of LED chips; the sealant layer is provided with a plurality of recesses on a side away from the LED chips, and the plurality of recesses are arranged above the plurality of LED chips in a one-to-one correspondence to the plurality of LED chips, so that light directly above the LED chips is opened to surroundings, and side light emission of the LED chips is increased, thereby increasing brightness of an area between adjacent ones of the LED chips, thus reducing a probability of dark shadows occurring.

### BRIEF DESCRIPTION OF DRAWINGS

In order to more clearly illustrate the embodiments or the technical solutions of the existing art, the drawings illustrating the embodiments or the existing art will be briefly described below. Obviously, the drawings in the following description merely illustrate some embodiments of the present invention. Other drawings may also be obtained by those skilled in the art according to these figures without paying creative work.

FIG. 1 is a schematic diagram of a first cross-sectional structure of a backlight module provided by an embodiment of the present application.

FIG. 2A is a schematic diagram of a first partial structure of the backlight module in FIG. 1.

FIG. 2B is a schematic diagram of a second partial structure of the backlight module in FIG. 1.

FIG. 2C is a schematic diagram of a third partial structure of the backlight module in FIG. 1.

FIG. 3A is a schematic diagram of a fourth partial structure of the backlight module in FIG. 1.

FIG. 3B is a schematic diagram of a fifth partial structure of the backlight module in FIG. 1.

FIG. 3C is a schematic diagram of a sixth partial structure of the backlight module in FIG. 1.

FIG. 3D is a schematic diagram of a seventh partial structure of the backlight module in FIG. 1.

FIG. 3E is a schematic diagram of an eighth partial structure of the backlight module in FIG. 1.

FIG. 3F is a schematic diagram of a ninth partial structure of the backlight module in FIG. 1.

FIG. 4 is a schematic diagram of a second cross-sectional structure of a backlight module provided by an embodiment of the present application.

Elements in the drawings are designated by reference numerals listed below.

1. substrate; 2. LED chip; 3. sealant layer; 31. sub-sealant layer; 4. recess; 41. first sub-recess; 42. second sub-recess.

### DETAILED DESCRIPTION OF PREFERRED EMBODIMENTS

The technical solutions in the embodiments of the present application will be clearly and completely described in the following with reference to the accompanying drawings in the embodiments. It is apparent that the described embodiments are only a part of the embodiments of the present application, and not all of them. All other embodiments obtained by a person skilled in the art based on the embodiments of the present application without creative efforts are within the scope of the present application. In addition, it should be understood that the specific implementations described here are only used to illustrate and explain the application, and are not used to limit the application. In the present application, unless otherwise stated, the orientation words used such as “upper” and “lower” generally refer to the upper and lower directions of the device in actual use or working state, and specifically refer to the drawing directions in the drawings, while “inner” and “outer” refer to the outline of the device.

It should be understood that when an element, layer, region, or component is referred to as being “on”, “connected to” or “coupled to” another element, layer, region, or component, the element, layer, region, or component may be directly on the another element, layer, region, or component; or directly connected to or directly coupled to the other element, layer, region, or component; and alternatively, there may be one or multiple intermediate elements, layers, regions, or components therebetween. However, “directly connected/directly coupled” means that one component is directly connected or combined with another component without intermediate components. Meanwhile, other expressions describing relationships between components such as “between”, “directly between” or “near to” and “directly adjacent to” can be similarly interpreted. In addition, it will also be understood that when an element or layer is referred to as being “between” two elements or layers, the element or layer can be the only element or layer located between the two elements or layers, or there may be one or more intermediate elements or layers between the two elements or layers.

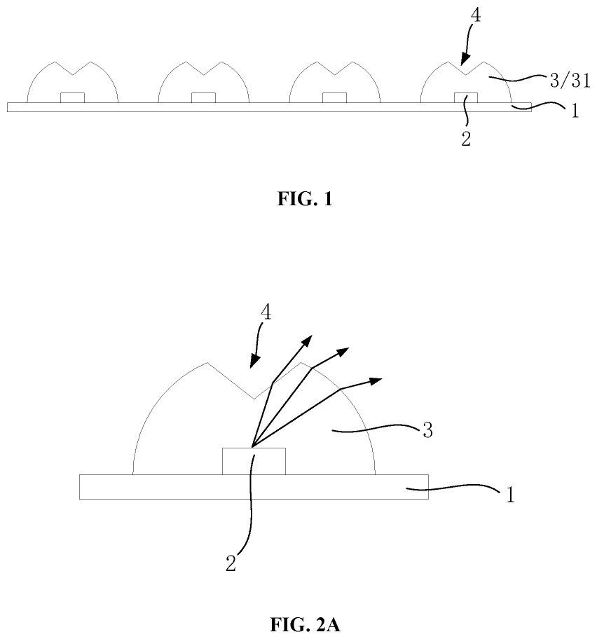

Referring to FIG. 1. FIG. 1 is a schematic diagram of a first cross-sectional structure of a backlight module provided by an embodiment of the present application. The backlight module includes a substrate 1, a plurality of LED chips 2, and a sealant layer 3. The plurality of LED chips 2 are arranged on the substrate 1 at intervals, and the sealant layer 3 is arranged on the substrate 1 and covers the plurality of LED chips 2. The sealant layer 3 is provided with a plurality of recesses 4 on a side away from the LED chips 2, and the plurality of recesses 4 are provided above the plurality of LED chips 2 in a one-to-one correspondence to the plurality of LED chips 2. As such, light directly above the LED chips 2 is opened to surroundings, and side light emission of the LED chips 2 is increased, thereby increasing brightness of an area between adjacent ones of the LED chips 2, thus reducing a probability of dark shadows occurring.

It should be noted that, in order to facilitate the description of the technical solution of the present application, an embodiment of the present application takes the LED chips 2 provided on the substrate 1 as an example for explanation.

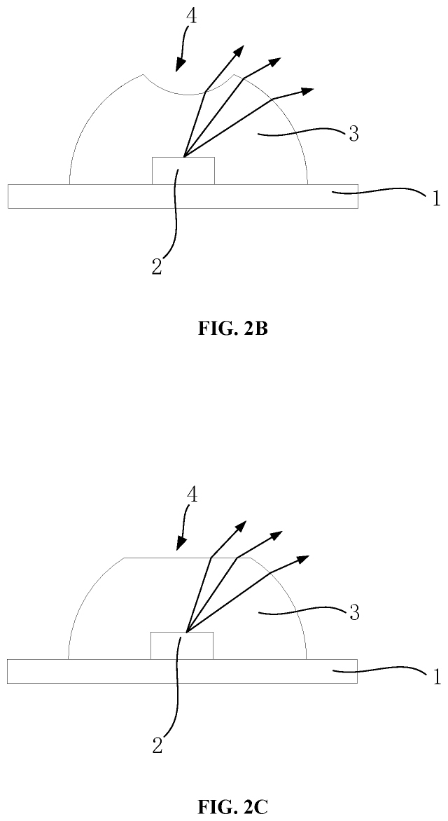

As shown in FIGS. 2A to 2C, the recesses 4 are provided above the LED chips 2, and a cross-sectional shape of each of the recesses 4 in a direction perpendicular to a surface of the substrate 1 is any one of a “V” shape, a “C” shape, or a “-” shape.

Specifically, in an embodiment, as shown in FIG. 2A, the cross-sectional shape of each of the recesses 4 in a direction perpendicular to the surface of the substrate 1 is a “V” shape.

Specifically, in an embodiment, as shown in FIG. 2B, the cross-sectional shape of each of the recesses 4 in the direction perpendicular to the surface of the substrate 1 is a “C” shape. It should be noted that in the embodiment of the present application, the cross-sectional shape of each of the recesses 4 in the direction perpendicular to the surface of the substrate 1 is actually a “C” shape, which is turned 90 degrees counterclockwise.

Specifically, in an embodiment, as shown in FIG. 2C, the cross-sectional shape of each of the recesses 4 in a direction perpendicular to the surface of the substrate 1 is a “-” shape.

Further, the LED chips 2 and the recesses 4 are symmetrically arranged with respect to a same symmetry axis, that is, the cross-sectional shapes of the LED chips 2 and the recesses 4 in the direction perpendicular to the surface of the substrate 1 are all symmetrical patterns, so that the left and right sides of the LED chips 2 emit light uniformly, which is beneficial to improve the display taste. Specifically, the cross-sectional shape of each of the LED chips 2 in the direction perpendicular to the surface of the substrate 1 in the embodiment of the present application may be rectangular.

Further, a width of each of the recesses 4 in a direction parallel to the surface of the substrate 1 is greater than a width of each of the LED chips 2 in the direction parallel to the surface of the substrate 1, so that the light emitted by the LED chips 2 is refracted as much as possible through the recesses 4, so that a larger angle of light emission can be achieved.

Further, since the distance between a bottom of the recesses 4 and the LED chips 2 in a direction perpendicular to the surface of the substrate 1 is greater, the deviation of an angle of the light emitted from the LED chips 2 and refracted through the recesses 4 from a position directly above the LED chips 2 is smaller, and the amount of light emitted from the side of the LED chips 2 is smaller, which is not conducive to reducing the probability of dark shadows occurring. Therefore, in the embodiment of the present application, the distance between the bottom of the recesses 4 and the LED chips 2 in the direction perpendicular to the surface of the substrate 1 should not be too large in order to meet the requirement of a large viewing angle.

Specifically, the substrate 1 may be a printed circuit board, for example, the substrate 1 may be a rigid circuit board, a flexible circuit board, or a rigid-flex board. The substrate 1 can be made of aluminum or ceramic materials.

Specifically, a material of the sealant layer 3 may be silicone.

Specifically, the LED chips 2 may adopt a front-mounted structure or a flip-chip structure, and embodiments of the present application are not particularly limited thereto.

In an embodiment of the present application, the recesses 4 and the sealant layer 3 are formed by the same manufacturing process, and the recesses 4 and the sealant layer 3 can be formed on the LED chips 2 by a process of glue dispensing, screen printing, or mold injection. Taking the backlight module in FIG. 1 as an example, the glue dispensing process specifically refers to vertically aligning a glue-filled dispenser head with a dispensing mold located between the dispenser head and the LED chips 2, wherein the dispensing mold has a preset pattern; first controlling the glue to drop a fixed amount into the dispensing mold; and then dispensing the glue in the dispensing mold to each of the LED chips 2 in turn. The screen printing process refers to using a screen printing plate to form a coating area, followed by scraping to form a fixed amount of glue, wherein the screen printing plate includes a number of meshes arranged at intervals, each of the meshes includes a non-inking area and an inking area surrounding the non-inking area, the inking area is an area that is permeable to ink, and the non-inking area is an area that is impermeable to ink. The non-inking areas are disposed corresponding to the recesses 4, the non-inking areas are disposed corresponding to the sealant layer 3, and a cross-sectional shape of each of the non-inking areas is tapered, so as to form the recesses 4. The mold injection process refers to using an already shaped mold to form a glue of a fixed shape in a mold groove by means of glue injection, and then moving the glue of a fixed shape onto the LED chips 2.

It is appreciated that the glue dispensing process and the screen printing process are to directly form the sealant layer 3 provided with the recesses 4, instead of secondary processing on the LED chip 2 after being molded by other processes, and compared with the mold injection process, the glue dispensing process and the screen printing process have a higher dispensing efficiency. The mold injection process is to prepare and form the sealant layer 3 provided with the recesses 4 in advance, and then arrange the sealant layer 3 on the LED chips 2. Compared with the glue dispensing process and the screen printing process, the dispensing accuracy is higher. In an actual production process, which process is specifically adopted to form the recesses 4 and the sealant layer 3 should be selected according to specific conditions, and the embodiment of the present application is not particularly limited thereto.

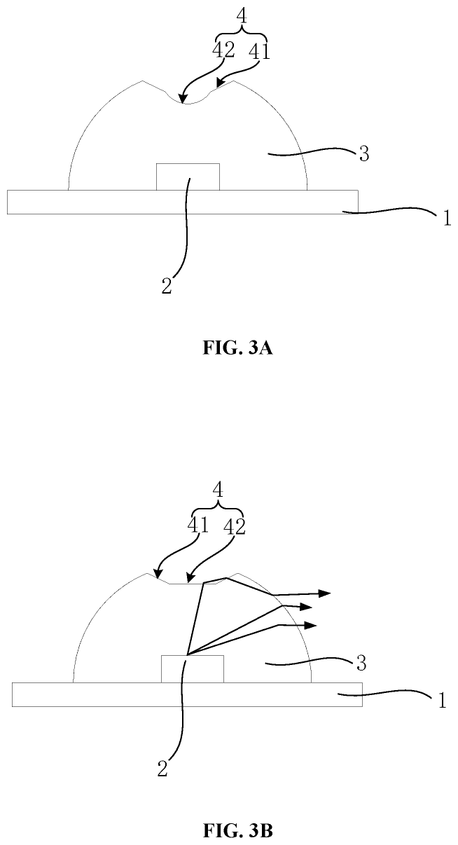

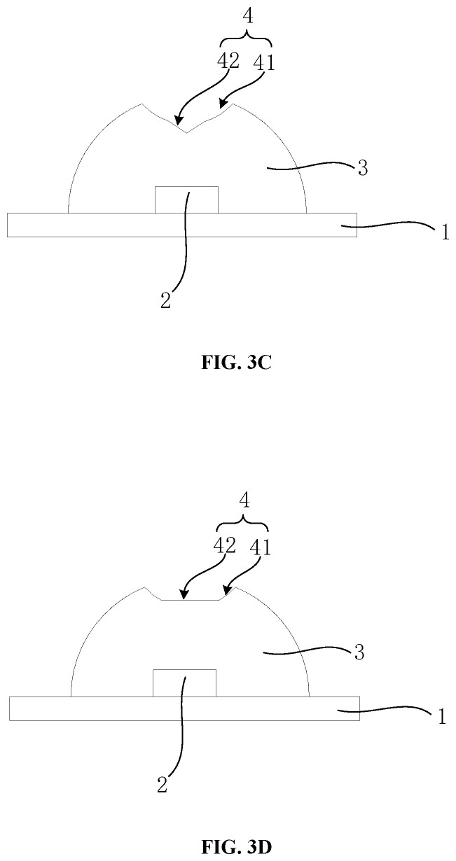

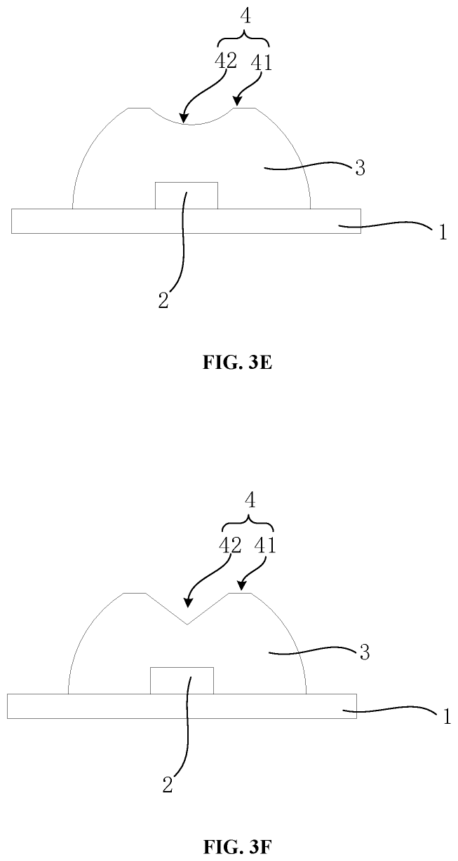

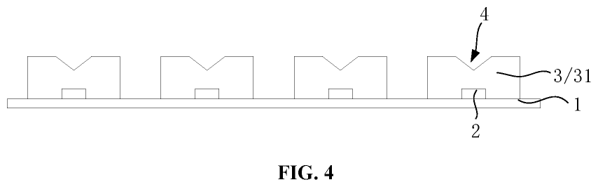

It should be noted that, in the backlight module shown in FIGS. 2A to 2C, the recesses 4 only include one sub-recess, however, the embodiment of the present application is not particularly limited thereto. Referring to FIGS. 3A to 3F, each of the recesses 4 may also include two sub-recesses to further achieve light emission at a larger angle.

Specifically, each of the recesses 4 includes a first sub-recess 41 and a second sub-recess 42 that are connected to each other. The first sub-recess 41 is recessed inwardly from a top of the sealant layer 3, and the second sub-recess 42 is further recessed inwardly from a bottom of the first sub-recess 41, and the first sub-recess 41 surrounds the second sub-recess 42.

Specifically, a shape of a cross-section of the second sub-recess 42 in a direction perpendicular to a surface of the substrate 1 is any one of a “V” shape, a “C” shape, or a “-” shape; a shape of a cross-section of the first sub-recess 41 in a direction perpendicular to the surface of the substrate 1 is an upper structure of any one of a “V” shape, a “C” shape, or a “-” shape, and the cross sections of the first sub-recess 41 and the second sub-recess 42 have different shapes in the direction perpendicular to the surface of the substrate 1.

Specifically, in an embodiment, as shown in FIG. 3A, the cross-sectional shape of the second sub-recess 42 in the direction perpendicular to the surface of the substrate 1 is a “C” shape, and the cross-sectional shape of the first sub-recess 41 in the direction perpendicular to the surface of the substrate 1 is selected from an upper structure of a “V” shape.

Specifically, in an embodiment, as shown in FIG. 3B, the cross-sectional shape of the second sub-recess 42 in the direction perpendicular to the surface of the substrate 1 is a “-” shape, and the cross-sectional shape of the first sub-recess 41 in the direction perpendicular to the surface of the substrate 1 is selected from an upper structure of a “V” shape.

Specifically, in an embodiment, as shown in FIG. 3C, the cross-sectional shape of the second sub-recess 42 in the direction perpendicular to the surface of the substrate 1 is a “V” shape, and the cross-sectional shape of the first sub-recess 41 in the direction perpendicular to the surface of the substrate 1 is selected from an upper structure of a “C” shape.

Specifically, in an embodiment, as shown in FIG. 3D, the cross-sectional shape of the second sub-recess 42 in the direction perpendicular to the surface of the substrate 1 is a “-” shape, and the cross-sectional shape of the first sub-recess 41 in the direction perpendicular to the surface of the substrate 1 is selected from an upper structure of a “C” shape.

Specifically, in an embodiment, as shown in FIG. 3E, the cross-sectional shape of the second sub-recess 42 in the direction perpendicular to the surface of the substrate 1 is a “V” shape, and the cross-sectional shape of the first sub-recess 41 in the direction perpendicular to the surface of the substrate 1 is selected from an upper structure of a “-” shape.

Specifically, in an embodiment, as shown in FIG. 3F, the cross-sectional shape of the second sub-recess 42 in the direction perpendicular to the surface of the substrate 1 is a “C” shape, and the cross-sectional shape of the first sub-recess 41 in the direction perpendicular to the surface of the substrate 1 is selected from an upper structure of a “-” shape.

It is appreciated that, taking FIG. 3A as an example, the light emitted by the LED chips 2 may be refracted multiple times after passing through the recesses. In detail, part of the light emitted by each of the LED chips 2 first undergoes a first refraction after passing through the second sub-recess 42, and is then incident into the air; next, it undergoes a second refraction after passing through the first sub-recess 41 and is then re-incident into the sealant layer 3; and it subsequently undergoes a third refraction after passing through an edge of the sealant layer 3 and is then incident onto a side of the LED chips 2. Compared with the recesses including only one sub-recess, in this case, the light emitted by the LED chips 2 can be refracted multiple times, thereby further increasing the side light emission of the LED chips 2, thus increasing the brightness of an area between adjacent ones of the LED chips 2 and reducing the probability of dark shadows occurring.

Further, the backlight module further includes an optical film set, the optical film set is arranged on a side of the sealant layer 3 away from the LED chips 2, and the optical film set includes optical films, such as a fluorescent film, a diffuser, and a brightness enhancement film.

Further, as shown in FIGS. 1 and 4, the sealant layer 3 includes a plurality of sub-sealant layers 31 distributed at intervals in a one-to-one correspondence to a plurality of the LED chips 2, and each of the sub-sealant layers 31 covers the corresponding one of the LED chips 2. Specifically, a cross-sectional shape of each of the sub-sealant layers 31 is arc or rectangular, for example, the cross-sectional shape of the sub-sealant layer 31 in FIG. 1 is arc; and the cross-sectional shape of the sub-sealant layer 31 in FIG. 4 is rectangular. Of course, the cross-sectional shapes of the sub-sealant layers 31 can also be other shapes, and the embodiments of the present application are not particularly limited thereto.

An embodiment of the present application also provides a display device, the display device includes the backlight module and the display panel in the above embodiments, the display panel is arranged on a side of the light-exiting surface of the backlight module, and the display panel may be a liquid crystal display panel, and the display device can be any product or component with a display function, such as a mobile phone, a tablet computer, a television, a monitor, a notebook computer, a digital photo frame, a navigator, etc.

Beneficial effects of the present application are that: the backlight module and display device provided by the present application include a substrate, a plurality of LED chips, and a sealant layer. The plurality of LED chips are arranged on the substrate at intervals, and the sealant layer is arranged on the substrate and covers the plurality of LED chips; the sealant layer is provided with a plurality of recesses on a side away from the LED chips, and the plurality of recesses are arranged above the plurality of LED chips in a one-to-one correspondence to the plurality of LED chips, so that light directly above the LED chips is opened to surroundings, and side light emission of the LED chips is increased, thereby increasing brightness of an area between adjacent ones of the LED chips, thus reducing a probability of dark shadows occurring.

While the invention has been described by way of example and in terms of the preferred embodiments, it is to be understood that the invention is not limited to the disclosed embodiments. To the contrary, it is intended to cover various modifications and similar arrangements. Therefore, the scope of the appended claims should be accorded the broadest interpretation so as to encompass all such modifications and similar arrangements.

1. A backlight module, comprising:
a substrate;
a plurality of LED chips arranged on the substrate at intervals; and
a sealant layer disposed on the substrate and covering the plurality of LED chips, wherein a material of the sealant layer comprises silicone;
wherein the sealant layer is provided with a plurality of recesses on a side away from the LED chips, and the plurality of recesses are arranged above the plurality of LED chips in a one-to-one correspondence to the plurality of LED chips.

2. The backlight module according to claim 1, wherein a shape of a cross-section of each of the recesses in a direction perpendicular to a surface of the substrate is any one of a “V” shape, a “C” shape, or a “-” shape.

3. The backlight module according to claim 1, wherein the LED chips and the recesses are symmetrically arranged with respect to a same symmetry axis.

4. The backlight module according to claim 3, wherein a width of each of the recesses in a direction parallel to a surface of the substrate is greater than a width of each of the LED chips in the direction parallel to the surface of the substrate.

5. The backlight module according to claim 1, wherein each of the recesses comprises a first sub-recess and a second sub-recess that are connected to each other, the first sub-recess is formed by recessing inwardly from a top of the sealant layer, the second sub-recess is further recessed inwardly from a bottom of the first sub-recess, and the first sub-recess surrounds the second sub-recess.

6. The backlight module according to claim 5, wherein a shape of a cross-section of the second sub-recess in a direction perpendicular to a surface of the substrate is any one of a “V” shape, a “C” shape, or a “-” shape, a shape of a cross-section of the first sub-recess in the direction perpendicular to the surface of the substrate is an upper structure of any one of a “V” shape, a “C” shape, or a “-” shape, and the cross sections of the first sub-recess and the second sub-recess have different shapes in the direction perpendicular to the surface of the substrate.

7. The backlight module according to claim 1, wherein the recesses and the sealant layer are formed by a same manufacturing process, and the recesses and the sealant layer are formed by a process of glue dispensing, screen printing, or mold injection.

8. The backlight module according to claim 1, wherein the sealant layer comprises a plurality of sub-sealant layers distributed at intervals in a one-to-one correspondence to the plurality of LED chips, and each of the sub-sealant layers covers a corresponding one of the LED chips.

9. The backlight module according to claim 8, wherein a shape of a cross-section of the sub-sealant layers is arc or rectangular.

10. The backlight module according to claim 1, wherein the backlight module further comprises an optical film set, and the optical film set is disposed on the side of the sealant layer away from the LED chips.

11. A backlight module, comprising:
a substrate;
a plurality of LED chips arranged on the substrate at intervals; and
a sealant layer disposed on the substrate and covering the plurality of LED chips;
wherein the sealant layer is provided with a plurality of recesses on a side away from the LED chips, and the plurality of recesses are arranged above the plurality of LED chips in a one-to-one correspondence to the plurality of LED chips.

12. The backlight module according to claim 11, wherein a shape of a cross-section of each of the recesses in a direction perpendicular to a surface of the substrate is any one of a “V” shape, a “C” shape, or a “-” shape.

13. The backlight module according to claim 11, wherein the LED chips and the recesses are symmetrically arranged with respect to a same symmetry axis.

14. The backlight module according to claim 13, wherein a width of each of the recesses in a direction parallel to a surface of the substrate is greater than a width of each of the LED chips in the direction parallel to the surface of the substrate.

15. The backlight module according to claim 11, wherein each of the recesses comprises a first sub-recess and a second sub-recess that are connected to each other, the first sub-recess is formed by recessing inwardly from a top of the sealant layer, the second sub-recess is further recessed inwardly from a bottom of the first sub-recess, and the first sub-recess surrounds the second sub-recess.

16. The backlight module according to claim 15, wherein a shape of a cross-section of the second sub-recess in a direction perpendicular to a surface of the substrate is any one of a “V” shape, a “C” shape, or a “-” shape, a shape of a cross-section of the first sub-recess in the direction perpendicular to the surface of the substrate is an upper structure of any one of a “V” shape, a “C” shape, or a “-” shape, and the cross sections of the first sub-recess and the second sub-recess have different shapes in the direction perpendicular to the surface of the substrate.

17. The backlight module according to claim 11, wherein the recesses and the sealant layer are formed by a same manufacturing process, and the recesses and the sealant layer are formed by a process of glue dispensing, screen printing, or mold injection.

18. The backlight module according to claim 11, wherein the sealant layer comprises a plurality of sub-sealant layers distributed at intervals in a one-to-one correspondence to the plurality of LED chips, and each of the sub-sealant layers covers a corresponding one of the LED chips.

19. The backlight module according to claim 18, wherein a shape of a cross-section of the sub-sealant layers is arc or rectangular.

20. A display device, comprising the backlight module according to claim 11, and a display panel disposed on a side of a light-exiting surface of the backlight module.
